(19) United States
(12) Patent Application Publication
(10) Pub. No.: US 2020/0373498 A1
(43) Pub. Date: Nov. 26, 2020

(54) ELECTRON TRANSPORT LAYER COMPRISING ZWITTERION LAYER, SOLAR CELL COMPRISING SAME AND METHOD OF MANUFACTURING SAME

(71) Applicant: POSTECH Research and Business Development Foundation, Pohang-si (KR)

(72) Inventors: Taiho PARK, Pohang-si (KR); Kyoungwon CHOI, Seoul (KR)

(21) Appl. No.: 16/846,676

(22) Filed: Apr. 13, 2020

(30) Foreign Application Priority Data
May 21, 2019 (KR) 10-2019-0059427

(51) Int. Cl. H01L 51/00

(52) U.S. Cl. CPC H01L 51/0067; H01L 51/442; H01L 51/0077

(57) ABSTRACT

Disclosed are an electron transport layer including a zwitterion layer, a solar cell including the same and a method of manufacturing the same. The electron transport layer includes a metal oxide layer including a metal oxide and a zwitterion layer formed on the metal oxide layer and including a zwitterion, thus exhibiting superior optoelectrical properties and stability. The solar cell includes the electron transport layer, thus solving hysteresis problems and exhibiting high photoelectric conversion efficiency and excellent resistance to various environmental factors (water, heat, light).

### CROSS REFERENCE TO RELATED APPLICATION

The present application claims priority based on Korean Patent Application No. 10-2019-0059427, filed on May 21, 2019, the entire content of which is incorporated herein for all purposes by this reference.

### BACKGROUND OF THE INVENTION

### 1. Technical Field

The present invention relates to an electron transport layer including a zwitterion layer, a solar cell including the same and a method of manufacturing the same, and more particularly to an electron transport layer including a zwitterion layer, thus having improved electrical properties, a solar cell including the same, thereby exhibiting increased cell efficiency and greatly improved water resistance, heat resistance and long-term stability, and a method of manufacturing the same.

### 2. Description of the Related Art

Organic-inorganic hybrid solar cells are showing high photoelectric conversion efficiency, and great progress is being made in the development thereof. In general, a perovskite material used in an organic-inorganic hybrid solar cell is a material having the crystal structure of ABX₃, particularly a material configured such that an organic material, an inorganic material and a halogen element are combined, thus showing high absorbance in the visible light range, enabling the movement of both electrons and holes, and exhibiting high mobility. Due to these characteristics, efficiency of over 24% has been reported for perovskite solar cells. However, since perovskite is easily broken down by external factors (water, heat, light, etc.), there is a disadvantage in that the stability of a solar cell manufactured using the same is low.

Typically, a perovskite solar cell is composed of the following layers: transparent electrode/electron transport layer/perovskite/hole transport layer/metal electrode. It is a so-called mesoporous structure when a porous support is additionally used for the electron transport layer, and a planar structure when such a porous support is not used.

Currently reported perovskite solar cells exhibit the highest photoelectric conversion efficiency when using a mesoporous-structure electron transport layer including a porous support. However, such a mesoporous-structure solar cell is disadvantageous because it requires at least two heat-treatment processes at temperatures exceeding 450° C. and thus the manufacturing process is complicated and also because it cannot be applied to upcoming flexible devices.

In a planar-structure solar cell, an n-type inorganic metal oxide used for an electron transport layer exhibits an appropriate energy level and high electron mobility, but the planar-structure solar cell still shows lower photoelectric conversion efficiency than a solar cell using a porous support, and has a hysteresis problem in which the efficiency varies depending on the direction of scanning of voltage. Hysteresis is somewhat affected by the ability of the charge transport layer to extract a charge, and in the case in which a charge is not effectively extracted, the charge accumulated at the interface between the charge transport layer and the perovskite acts as a defect, thus lowering the performance and stability of the perovskite solar cell.

Therefore, there is urgent need for an electron transport layer having high charge extraction ability and an effect of delaying breakdown of a photoconversion layer, a high-efficiency and high-stability organic/inorganic solar cell including the same, and a method for manufacturing the same.

### SUMMARY OF THE INVENTION

Accordingly, the present invention has been made keeping in mind the problems encountered in the related art, and an objective of the present invention is to provide an electron transport layer, which increases a potential difference and enables efficient charge extraction by moving the work function of metal oxide, improves transport capacity, and suppresses the process whereby electrons are transferred back to the perovskite layer and recombined with holes.

Another objective of the present invention is to provide an organic-inorganic hybrid solar cell, which is able to solve hysteresis problems and exhibits high photoelectric conversion efficiency and excellent resistance to various environmental factors (water, heat, light, etc.), and a method of manufacturing the same.

An aspect of the present invention provides a modified electron transport layer, including: a metal oxide layer including a metal oxide and a zwitterion layer formed on the metal oxide layer and including a zwitterion.

Also, the metal oxide may be an n-type metal oxide.

Also, the metal oxide may include at least one selected from the group consisting of SnO₂, ZnO, TiO₂, Al₂O₃, MgO, Fe₂O₃, WO₃, In₂O₃, BaTiO₃, BaSnO₃ and ZrO₃.

Also, the zwitterion may include at least one selected from the group consisting of a compound represented by Structural Formula 1 below and a compound represented by Structural Formula 2 below:

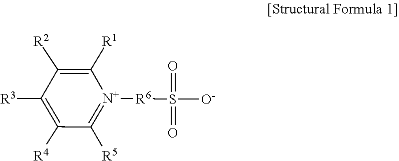

in Structural Formula 1,

R¹ to R⁵ are the same as or different from each other, and are each independently a hydrogen atom, a linear C1 to C9 alkyl group, or a branched C3 to C9 alkyl group, and

R⁶ is a linear C1 to C9 alkylene group or a branched C2 to C9 alkylene group; and

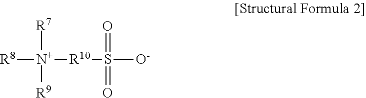

in Structural Formula 2,

R⁷ to R⁹ are the same as or different from each other, and are each independently a hydrogen atom, a linear C1 to C9 alkyl group, or a branched C3 to C9 alkyl group, and

R¹⁰ is a linear C1 to C9 alkylene group or a branched C2 to C9 alkylene group.

Also, R¹ to R⁵ may be the same as or different from each other, and may be each independently a hydrogen atom or a linear C1 to C9 alkyl group, R⁶ may be a linear C1 to C9 alkylene group, R⁷ to R⁹ may be the same as or different from each other, and may be each independently a hydrogen atom or a linear C1 to C9 alkyl group, and R¹⁰ may be a linear C1 to C9 alkylene group.

Also, the metal oxide layer may have a thickness of 10 to 60 nm.

Also, the zwitterion layer may have a thickness of 0.5 to 10 nm.

Also, the electron transport layer may be used as an electron transport layer for a solar cell.

Another aspect of the present invention provides a solar cell, including: a first electrode, a metal oxide layer formed on the first electrode and including a metal oxide, a zwitterion layer formed on the metal oxide layer and including a zwitterion, a photoconversion layer formed on the zwitterion layer, a hole transport layer formed on the photoconversion layer, and a second electrode formed on the hole transport layer.

Also, the photoconversion layer may include at least one selected from the group consisting of a perovskite-structured compound, a dye and a quantum dot.

Also, the perovskite-structured compound may include at least one selected from the group consisting of CH₃NH₃PbI₃₋ₓClₓ (0≤x≤3, a real number), CH₃NH₃PbI₃₋ₓBrₓ (0≤x≤3, a real number), CH₃NH₃PbCl₃₋ₓBrₓ (0≤x≤3, a real number), CH₃NH₃PbI₃₋ₓFₓ (0≤x≤3, a real number), NH₂CH═NH₂PbI₃₋ₓClₓ (0≤x≤3, a real number), NH₂CH═NH₂PbI₃₋ₓBrₓ (0≤x≤3, a real number), NH₂CH═NH₂PbCl₃₋ₓBrₓ (0≤x≤3, a real number), NH₂CH═NH₂PbI₃₋ₓFₓ (0≤x≤3, a real number), Csₓ (MA_{0.17}FA_{0.83})₍₁₋ₓ₎Pb (I_{0.83}Br_{0.17})₃ (0≤x≤1, a real number) and Csₖ(NH₂CH═NH₂PbI₃)₍₁₋ₖ₋ₓ₎(CH₃NH₃PbBr₃)ₓ (0≤k≤0.3, a real number, and 0≤x≤1−k, a real number).

Also, the hole transport layer may include at least one selected from the group consisting of Spiro-OMeTAD, P3HT, P3AT, P3OT, PEDOT:PSS, PTAA and a conductive polymer.

Also, the first electrode may include at least one selected from the group consisting of indium tin oxide (ITO), fluorine tin oxide (FTO), indium zinc oxide (IZO), indium zinc tin oxide (IZTO), aluminum zinc oxide (AZO), indium tin oxide-silver-indium tin oxide (ITO—Ag—ITO), indium zinc oxide-silver-indium zinc oxide (IZO—Ag—IZO), indium zinc tin oxide-silver-indium zinc tin oxide (IZTO—Ag—IZTO) and aluminum zinc oxide-silver-aluminum zinc oxide (AZO—Ag—AZO).

Also, the second electrode may include at least one selected from the group consisting of Ag, Au, Al, Fe, Cu, Cr, W, Mo, Zn, Ni, Pt, Pd, Co, In, Mn, Si, Ta, Ti, Sn, Pb, V, Ru, Ir, Zr, Rh and Mg.

Also, the solar cell may be any one selected from the group consisting of a dye-sensitized solar cell, a perovskite solar cell and a quantum-dot solar cell.

Still another aspect of the present invention provides a method of manufacturing a solar cell, including: (a) forming a metal oxide layer including a metal oxide on a first electrode, (b) forming a zwitterion layer including a zwitterion on the metal oxide layer, (c) forming a photoconversion layer on the zwitterion layer, (d) forming a hole transport layer on the photoconversion layer, and (e) forming a second electrode on the hole transport layer.

Also, step (b) may be performed through at least one process selected from the group consisting of spin coating and chemical bath deposition.

Also, the metal oxide layer may have a thickness of 10 to 60 nm, and the zwitterion layer may have a thickness of 0.5 to 10 nm.

According to the present invention, a modified electron transport layer includes a metal oxide layer and a zwitterion layer, whereby an increased potential difference and efficient charge extraction can be realized by moving the work function of the metal oxide, transport capacity is improved, and the process whereby electrons are transferred back to the perovskite layer and recombined with holes can be suppressed.

In addition, a solar cell including the electron transport layer of the present invention solves the hysteresis problem, and has an effect of having high photoelectric conversion efficiency and excellent resistance to various environmental factors (water, heat, light, etc.).

### BRIEF DESCRIPTION OF DRAWINGS

Since these drawings are for reference in describing exemplary embodiments of the present invention, the technical spirit of the present invention should not be construed as being limited to the accompanying drawings, in which:

FIG. 1 schematically shows an electron transport layer according to an embodiment of the present invention;

FIG. 2 is a cross-sectional view showing a solar cell according to an embodiment of the present invention;

FIG. 3A schematically shows a solar cell manufactured in Example 1 and an electron transport layer;

FIG. 3B shows the FTIR spectrum of the surface of the SnO₂ metal oxide layer in Example 1 and Comparative Example 1;

FIG. 3C shows the XPS spectrum of the electron transport layer in Example 1 and Comparative Example 1;

FIG. 3D shows the UV photoelectron spectrum of the electron transport layer in the solar cell manufactured in Example 1 and Comparative Example 1;

FIG. 3E shows the energy diagram of the solar cell manufactured in Example 1;

FIG. 4 is SEM images showing the cross section of the electron transport layer/photoactive layer depending on the heat treatment time at 150° C. of the solar cell manufactured in Example 1 and Comparative Example 1;

FIG. 5 shows the results of evaluation of stability depending on the temperature of the solar cell manufactured in Example 1 and Comparative Example 1;

FIG. 6 shows actual cell changes based on the evaluation of stability depending on the temperature of the solar cell manufactured in Example 1 and Comparative Example 1; and

FIG. 7 shows the results of evaluation of stability under high-temperature and high-humidity conditions of the solar cell manufactured in Example 1 and Comparative Example 1; and

FIG. 8 shows the current density-voltage curve after 140 hr of the solar cell manufactured in Example 1 and Comparative Example 1.

### DESCRIPTION OF SPECIFIC EMBODIMENTS

Hereinafter, exemplary embodiments of the present invention are described in detail with reference to the appended drawings so as to be easily performed by a person having ordinary skill in the art.

However, the following description does not limit the present invention to specific embodiments, and in the description of the present invention, detailed descriptions of related known techniques incorporated herein will be omitted when the same may make the gist of the present invention unclear.

The terms herein are used to explain specific embodiments, and are not intended to limit the present invention. Unless otherwise stated, a singular expression includes a plural expression. In this application, the terms “include” or “have” are used to designate the presence of features, numbers, steps, operations, elements, parts, or combinations thereof described in the specification, and should be understood as not excluding the presence or additional possible presence of one or more different features, numbers, steps, operations, elements, parts, or combinations thereof.

As used herein, the terms “first”, “second”, etc. may be used to describe various elements, but these elements are not to be limited by these terms. These terms are only used to distinguish one element from another. For example, a first element may be termed a second element, and similarly, a second element may be termed a first element, without departing from the scope of the present invention.

Further, it will be understood that when an element is referred to as being “formed” or “stacked” on another element, it can be formed or stacked so as to be directly attached to all surfaces or to one surface of the other element, or intervening elements may be present therebetween.

Hereinafter, a detailed description will be given of an electron transport layer including a zwitterion layer, a solar cell including the same and a method of manufacturing the same according to the present invention, which is set forth to illustrate but is not to be construed as limiting the present invention, and the present invention is defined only by the accompanying claims.

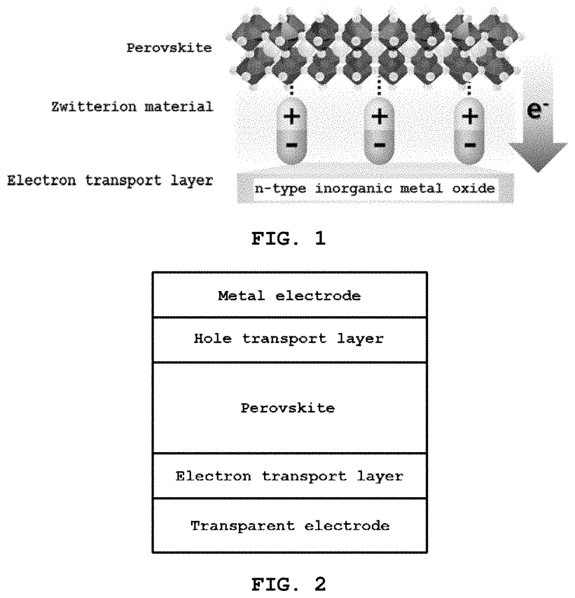

FIG. 1 schematically shows an electron transport layer according to the present invention.

With reference to FIG. 1, the present invention pertains to a modified electron transport layer, which includes a metal oxide layer including a metal oxide and a zwitterion layer formed on the metal oxide layer and including a zwitterion.

The zwitterion functions to move the work function of the metal oxide on the surface of the metal oxide layer, resulting in an increased potential difference and efficient charge extraction, and the ions of the surface improve the transport capacity of the electron transport layer and suppress the process whereby electrons are transferred back to the perovskite layer and recombined with holes, and the positive charge of the zwitterion serves to improve stability by passivating lead-iodine antisite defects.

Further, the metal oxide may be an n-type metal oxide.

Also, the metal oxide layer may include at least one selected from the group consisting of SnO₂, ZnO, TiO₂, Al₂O₃, MgO, Fe₂O₃, WO₃, In₂O₃, BaTiO₃, BaSnO₃ and ZrO₃, preferably includes at least one selected from the group consisting of SnO₂, ZnO and TiO₂, and more preferably includes SnO₂.

Also, the zwitterion may include at least one selected from the group consisting of a compound represented by Structural Formula 1 below and a compound represented by Structural Formula 2 below.

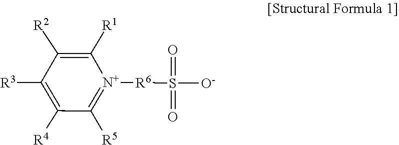

In Structural Formula 1,

R¹ to R⁵ are the same as or different from each other, and are each independently a hydrogen atom, a linear C1 to C9 alkyl group or a branched C3 to C9 alkyl group, and

R⁶ is a linear C1 to C9 alkylene group or a branched C2 to C9 alkylene group.

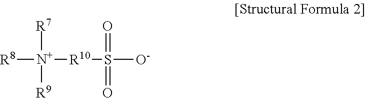

In Structural Formula 2,

R⁷ to R⁹ are the same as or different from each other, and are each independently a hydrogen atom, a linear C1 to C9 alkyl group or a branched C3 to C9 alkyl group, and

R¹⁰ is a linear C1 to C9 alkylene group or a branched C2 to C9 alkylene group.

Also, R¹ to R⁵ are the same as or different from each other, and are each independently a hydrogen atom or a linear C1 to C9 alkyl group, R⁶ is a linear C1 to C9 alkylene group, R⁷ to R⁹ are the same as or different from each other, and are each independently a hydrogen atom or a linear C1 to C9 alkyl group, and R¹⁰ is a linear C1 to C9 alkylene group.

Preferably, R¹ to R⁵ are a hydrogen atom, R⁶ is a linear C1 to C5 alkylene group, R⁷ to R⁹ are the same as or different from each other and are each independently a hydrogen atom or a linear C1 to C3 alkyl group, and R¹⁰ is a linear C1 to C5 alkylene group.

More preferably, R¹ to R⁵ are a hydrogen atom, R⁶ is a linear C2 to C4 alkylene group, R⁷ to R⁹ are the same as or different from each other and are each independently a hydrogen atom or a linear C1 to C3 alkyl group, and R¹⁰ is a linear C2 to C4 alkylene group.

Also, the thickness of the metal oxide layer is 10 to 60 nm, preferably 20 to 50 nm, and more preferably 30 to 40 nm. If the thickness of the metal oxide layer is less than 10 nm, surface defects may occur because the first electrode cannot be uniformly and completely applied, and the process of recombination of electrons and holes cannot be effectively limited. On the other hand the thickness thereof exceeds 60 nm, resistance may increase due to the increased movement distance of electrons, resulting in lowered efficiency.

Also, the thickness of the zwitterion layer is 0.5 to 10 nm, preferably 2 to 8 nm, and more preferably 3 to 5 nm. If the thickness of the zwitterion layer is less than 0.5 nm, the effect generated by the formation of the zwitterion layer may be small. On the other hand, if the thickness thereof exceeds 10 nm, the zwitterion layer may act as an insulator that inhibits electron movement, and thus increased resistance and lowered efficiency may result.

Moreover, the electron transport layer may be used as an electron transport layer of a solar cell.

FIG. 2 is a cross-sectional view of a solar cell according to the present invention.

With reference to FIG. 2, the present invention pertains to a solar cell, which includes a first electrode, a metal oxide layer formed on the first electrode and including a metal oxide, a zwitterion layer formed on the metal oxide layer and including a zwitterion, a photoconversion layer formed on the zwitterion layer, a hole transport layer formed on the photoconversion layer, and a second electrode formed on the hole transport layer.

Also, the photoconversion layer may include at least one selected from the group consisting of a perovskite-structured compound, a dye and a quantum dot.

The perovskite-structured compound may include at least one selected from the group consisting of CH₃NH₃PbI₃₋ₓClₓ (0≤x≤3, a real number), CH₃NH₃PbI₃₋ₓBrₓ (0≤x≤3, a real number), CH₃NH₃PbCl₃₋ₓBrₓ (0≤x≤3, a real number), CH₃NH₃PbI₃₋ₓFₓ (0≤x≤3, a real number), NH₂CH═NH₂PbI₃₋ₓClₓ (0≤x≤3, a real number), NH₂CH═NH₂PbI₃₋ₓBrₓ (0≤x≤3, a real number), NH₂CH═NH₂PbCl₃₋ₓBrₓ (0≤x≤3, a real number), NH₂CH═NH₂PbI₃₋ₓFₓ (0≤x≤3, a real number), Csₓ (MA_{0.17}FA_{0.83})₍₁₋ₓ)Pb(I_{0.83}Br_{0.17})₃ (0≤x≤3, a real number) and Csₖ(NH₂CH═NH₂PbI₃)₍₁₋ₖ₋ₓ₎ (CH₃NH₃PbBr₃)ₓ (0≤k≤0.3, a real number, and 0≤x≤1−k, a real number), preferably includes Csₓ(MA_{0.17}FA_{0.83})₍₁₋ₓ₎Pb (I_{0.83}Br_{0.17})₃ (0≤x≤1, a real number), and more preferably includes Cs_{0.05} (MA_{0.17}FA_{0.83})_{0.95}Pb (I_{0.83}Br_{0.17})₃.

Also, the hole transport layer may include at least one selected from the group consisting of Spiro-OMeTAD, P3HT, P3AT, P3OT, PEDOT:PSS, PTAA and a conductive polymer, and preferably includes Spiro-OMeTAD.

The hole transport layer may include, as a dopant, at least one selected from the group consisting of Li-TFSI, Co(II) PF₆, 4-tert-butylpyridine (tBP), AgTFSI and CuI, and preferably includes at least one selected from the group consisting of Li-TFS and 4-tert-butylpyridine (tBP).

Also, the first electrode may include at least one selected from the group consisting of indium tin oxide (ITO), fluorine tin oxide (FTO), indium zinc oxide (IZO), indium zinc tin oxide (IZTO), aluminum zinc oxide (AZO), indium tin oxide-silver-indium tin oxide (ITO—Ag—ITO), indium zinc oxide-silver-indium zinc oxide (IZO—Ag—IZO), indium zinc tin oxide-silver-indium zinc tin oxide (IZTO—Ag—IZTO) and aluminum zinc oxide-silver-aluminum zinc oxide (AZO—Ag—ZO), and preferably includes fluorine tin oxide (FTO).

Also, the second electrode may include at least one selected from the group consisting of Ag, Au, Al, Fe, Cu, Cr, W, Mo, Zn, Ni, Pt, Pd, Co, In, Mn, Si, Ta, Ti, Sn, Pb, V, Ru, Ir, Zr, Rh and Mg, preferably includes Ag, and more preferably includes Au.

Moreover, the solar cell may be any one selected from the group consisting of a dye-sensitized solar cell, a perovskite solar cell and a quantum-dot solar cell, and is preferably a perovskite solar cell.

In addition, the present invention pertains to a method of manufacturing a solar cell, which includes (a) forming a metal oxide layer including a metal oxide on a first electrode, (b) forming a zwitterion layer including a zwitterion on the metal oxide layer, (c) forming a photoconversion layer on the zwitterion layer, (d) forming a hole transport layer on the photoconversion layer, and (e) forming a second electrode on the hole transport layer.

Here, step (b) may be performed through at least one process selected from the group consisting of spin coating and chemical bath deposition.

Also, the thickness of the metal oxide layer is 10 to 60 nm, preferably 20 to 50 nm, and more preferably 30 to 40 nm. If the thickness of the metal oxide layer is less than 10 nm, surface defects may occur because the first electrode cannot be uniformly and completely applied, and moreover, the process of recombination of electrons and holes cannot be effectively limited. On the other hand, if the thickness thereof exceeds 60 nm, resistance may increase due to the increased movement distance of electrons, resulting in lowered efficiency.

Also, the thickness of the zwitterion layer is 0.5 to 10 nm, preferably 2 to 8 nm, and more preferably 3 to 5 nm. If the thickness of the zwitterion layer is less than 0.5 nm, the effect generated by the formation of the zwitterion layer may be small. On the other hand, if the thickness thereof exceeds 10 nm, the zwitterion layer may act as an insulator that inhibits electron movement, and thus increased resistance and lowered efficiency may result.

### EXAMPLES

A better understanding of the present invention will be given through the following examples, which are merely set forth to illustrate the present invention but are not to be construed as limiting the scope of the present invention.

### Example 1: Solar Cell

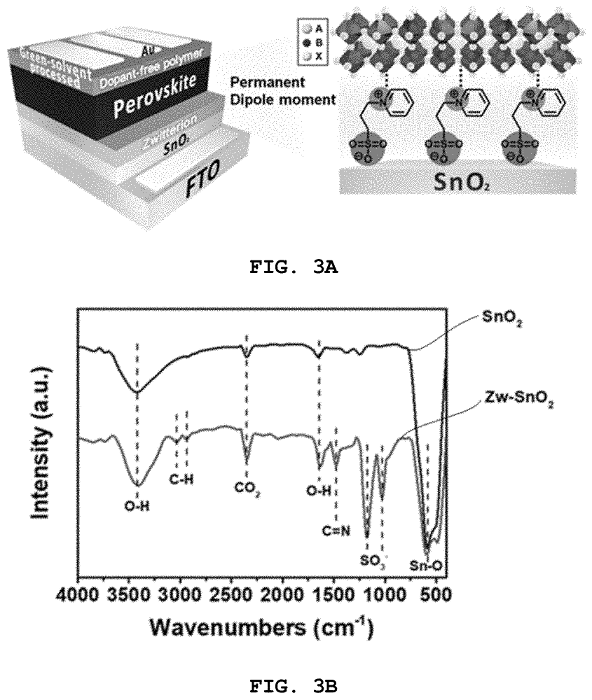

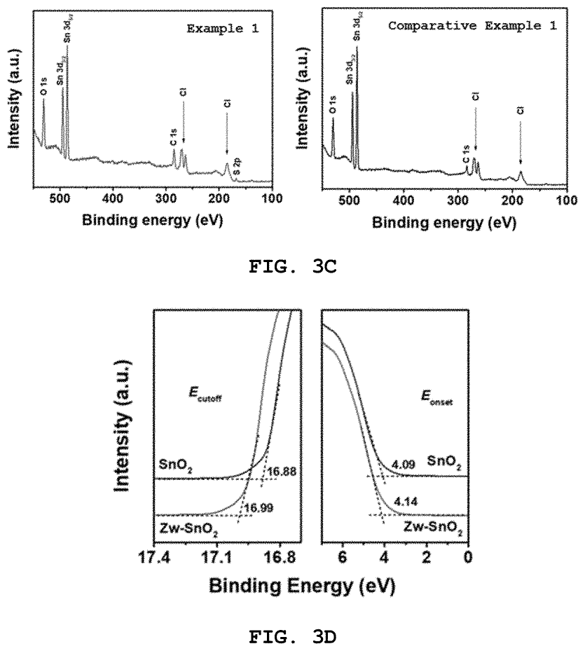

FIG. 3A schematically shows a solar cell manufactured in Example 1 and an electron transport layer. With reference to FIG. 3A, the solar cell of Example 1 is manufactured as follows.

As a first electrode, FTO (F-doped SnO₂, 8 ohms/cm², Pilkington) was used. A portion of FTO was etched with a 2 M HCl solution and a Zn powder and then washed with deionized water, ethanol, acetone and isopropanol. Thereafter, UV ozone treatment was performed for 15 min, thus removing organic residues.

A SnO₂ precursor solution, obtained by dissolving 112.8 mg of SnCl₂.H₂O in 5 ml of ethanol, was applied through spin coating at 2,000 rpm for 30 sec on the first electrode, and then heat-treated at 200° C. for 30 min, thus forming a SnO₂ metal oxide layer having a thickness of about 40 nm.

A zwitterion 3-(1-pyridinio)-1-propanesulfonate was dissolved at a concentration of 0.4 wt % in methanol or deionized water, applied through spin coating at 5,000 rpm for 60 sec on the metal oxide layer, and then heat-treated at 100° C. for 10 min, thus forming a zwitterion layer having a thickness of 5 nm.

A solution, obtained by dissolving 1 M CH(NH₂)₂I (formamidinium iodide, FAI), 0.2 M CH₃NH₃Br (methylammonium bromide, MABr), 0.22 M PbBr₂, and 1.1 M PbI₂ in 1 ml of a mixed solvent of dimethylformamide (DMF) and dimethyl sulfoxide (DMSO) at a volume ratio of 4:1, was mixed with 1.5 M CsI in dimethyl sulfoxide (DMSO) at a volume ratio of 95:1, thus preparing a Cs_{0.05} (MA_{0.17}FA_{0.83})_{0.95}Pb(I_{0.83}Br_{0.17})₃ perovskite precursor solution. The perovskite precursor solution was applied through spin coating at 1,000 rpm for 10 sec and at 6,000 rpm for 20 sec on the electron transport layer, and chlorobenzene was sprayed thereon 5 sec before termination of spin coating, followed by heat treatment at 100° C. for 45 min, thus forming a photoconversion layer having a perovskite structure with a thickness of about 500 nm.

A Spiro-MeOTAD (Merck KGaA) chlorobenzene solution (72.3 mg/1 ml) was added with 27.8 μl of t-BP (Sigma-Aldrich) and 17.5 μl of Li-TFSI (Sigma-Aldrich) (520 mg/1 ml in AN (acetonitrile)) as dopants and stirred at 70° C. for 12 hr, thus preparing a hole transport layer precursor solution. The hole transport layer precursor solution was applied through spin coating at 5000 rpm for 30 sec on the photoconversion layer, thus forming a hole transport layer.

Subsequently, silver (Ag) or gold (Au) was deposited to a thickness of 100 nm on the hole transport layer in a vacuum chamber having a vacuum level of 10⁻⁷ torr or less to form a second electrode, thereby manufacturing a solar cell.

### Example 2: Solar Cell

A solar cell was manufactured in the same manner as in Example 1, with the exception that a SnO₂ metal oxide layer was formed through both spin coating and chemical bath deposition (CBD), in lieu of spin coating alone.

The SnO₂ metal oxide layer was formed using chemical bath deposition as follows. Specifically, a SnO₂ precursor solution, obtained by dissolving 112.8 mg of SnCl₂.H₂O in 5 ml of ethanol, was applied through spin coating at 2,000 rpm for 30 sec on the first electrode, and then heat-treated at 200° C. for 30 min, thus forming a SnO₂ metal oxide layer having a thickness of about 40 nm.

0.5 g of urea was dissolved in 40 ml of deionized water, added with a solution of 10 μl of thioglycolic acid (mercaptoacetic acid) and 0.5 ml of HCl (37 wt %) and 0.012 M SnCl₂.H₂O, and stirred for 2 min, thus preparing a solution. The metal oxide layer was vertically immersed in the solution, heat-treated at 70° C. for 3 hr, and then washed with deionized water. Thereafter, heat treatment at 180° C. for 1 hr was performed, thereby effectively removing the defects of a SnO₂ metal oxide layer having a thickness of about 40 nm through chemical bath deposition, resulting in a uniform metal oxide layer.

### Comparative Example 1: Solar Cell

A solar cell was manufactured in the same manner as in Example 1, with the exception that a zwitterion layer including a zwitterion was not formed when forming an electron transport layer.

### Test Examples

### Test Example 1: Presence of Zwitterion in Electron Transport Layer and Effect Thereof

FIG. 3B shows the FTIR spectrum of the surface of the SnO₂ metal oxide layer in Example 1 and Comparative Example 1, and FIG. 3C shows the XPS spectrum of the electron transport layer in Example 1 and Comparative Example 1. FIG. 3D shows the UV photoelectron spectrum of the electron transport layer in the solar cell manufactured in Example 1 and Comparative Example 1, and FIG. 3E shows the energy diagram of each layer of the solar cell manufactured in Example 1.

As shown in FIG. 3B, the surface of the SnO₂ metal oxide layer exhibited the absorption band of Sn—O at 500 cm⁻¹, and also, a new peak appeared due to the reaction with the zwitterion. The SO₃⁻ absorption band at 1100 cm⁻¹ and 1200 cm⁻¹, the C═N absorption band at 1600 cm⁻¹, and the C—H absorption band at 3000 cm⁻¹ showed that the cation in the zwitterion was successfully introduced to the surface of the SnO₂ metal oxide layer.

As shown in FIG. 3C, compared to Comparative Example 1, in the XPS spectrum of Example 1, the O 1 s peak (˜530 eV) and C 1 s peak (˜284 eV) intensities increased. Moreover, the S 2 p peak (˜167 eV) appeared in Example 1.

As shown in FIG. 3D, in the UV photoelectron spectrum, there was an obvious difference between Example 1 and Comparative Example 1. The energy diagram of FIG. 3E was represented by calculating the values of work function (WF) and valence band maximum (VBM) values from the UV photoelectron spectrum of FIG. 3D.

As shown in FIG. 3E, the work function of SnO₂ was moved from 4.34 eV to 4.23 eV. This change in energy level is deemed to be due to the dipole effects of the zwitterion molecule.

### Test Example 2: Measurement of Driving Efficiency of Perovskite Solar Cell

Table 1 below shows the results of a comparison of the properties of the solar cells manufactured in Examples 1 and 2 and Comparative Example 1.

TABLE 1

| | Optical short- | | | | | | Energy | |
|---|---|---|---|---|---|---|---|---|
| | circuit current | | Optical open | | Fill | | conversion | |
| | density | | voltage | | factor | | efficiency | |
| | (JSC, mA/cm²) | | (VOC, V) | | (FF) | | (%) | |
| No. | For. | Rev. | For. | Rev. | For. | Rev. | For. | Rev. |
| Example 1 | 23.4 | 23.2 | 1.13 | 1.14 | 74.1 | 78.8 | 19.60 | 20.91 |
| Example 2 | 23.4 | 23.6 | 1.13 | 1.16 | 76.8 | 78.4 | 20.32 | 21.43 |
| Comparative | 22.5 | 23.0 | 1.05 | 1.10 | 71.3 | 77.6 | 16.80 | 19.63 |
| Example 1 | | | | | | | | |

As is apparent from Table 1, the solar cells manufactured in Examples 1 and 2 exhibited higher optical short-circuit current density, optical open voltage and fill factor than the solar cell manufactured in Comparative Example 1. Moreover, the efficiency of the solar cell manufactured in Example 2 was increased by about 9% compared to that of the solar cell manufactured in Comparative Example 1.

Therefore, it can be concluded that the electron transport layer according to the present invention exhibits superior optoelectrical properties.

### Test Example 3: Evaluation of Stability of Solar Cell at High Temperature

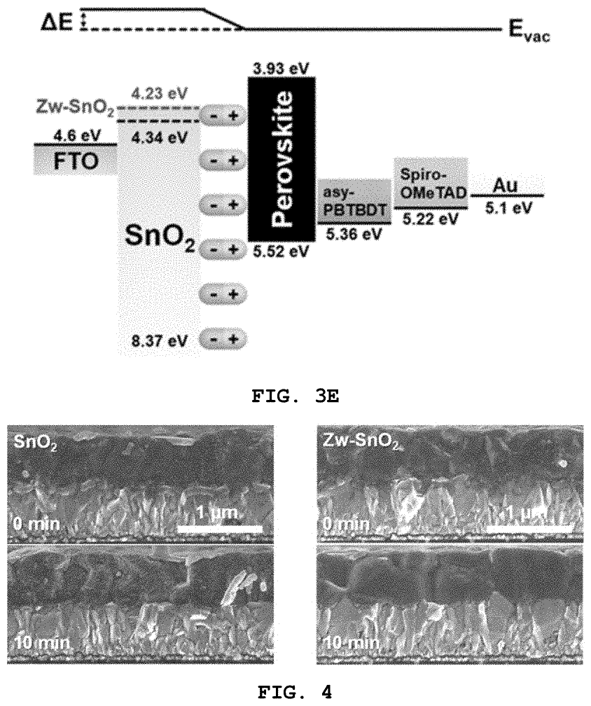

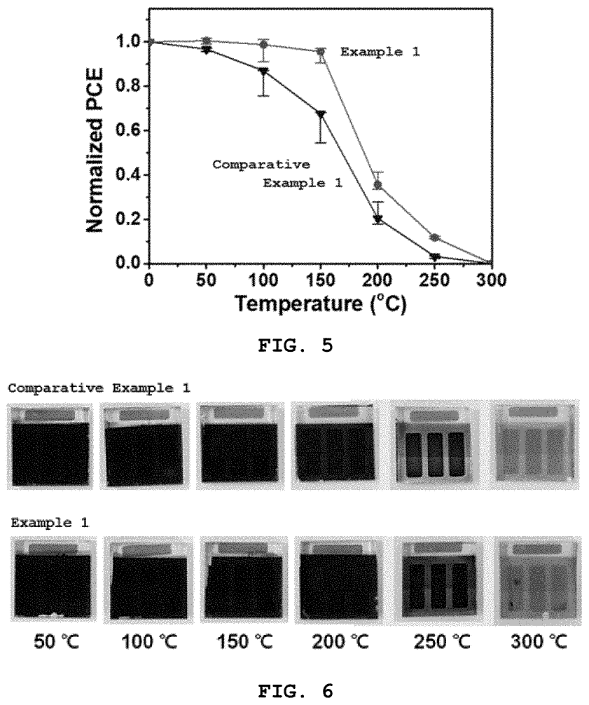

FIG. 4 is SEM images showing the cross section of the electron transport layer/photoconversion layer depending on the heat treatment time at 150° C. of the solar cell manufactured in Example 1 and Comparative Example 1, FIG. 5 shows the results of evaluation of stability depending on the temperature of the solar cell manufactured in Example 1 and Comparative Example 1, and FIG. 6 shows actual cell changes based on the evaluation of stability depending on the temperature of the solar cell manufactured in Example 1 and Comparative Example 1.

The evaluation of stability at different temperatures was performed in a manner in which the solar cell of Example 1 and Comparative Example 1 was heated to temperatures of 50° C., 100° C., 150° C., 200° C., 250° C. and 300° C. at a humidity of about 25% for 10 min and the efficiency thereof was measured.

As shown in FIGS. 4 to 6, the breakdown of the photoconversion layer (breakdown of perovskite) was slower in the solar cell of Example 1 than in the solar cell of Comparative Example 1. Moreover, the extent of reduction relative to the initial photoelectric conversion efficiency was decreased.

Therefore, it can be concluded that the solar cell manufactured in Example 1 exhibits superior stability even at high temperatures.

### Test Example 4: Evaluation of Stability of Solar Cell Under Long-Term Exposure to High-Temperature High-Humidity Environment

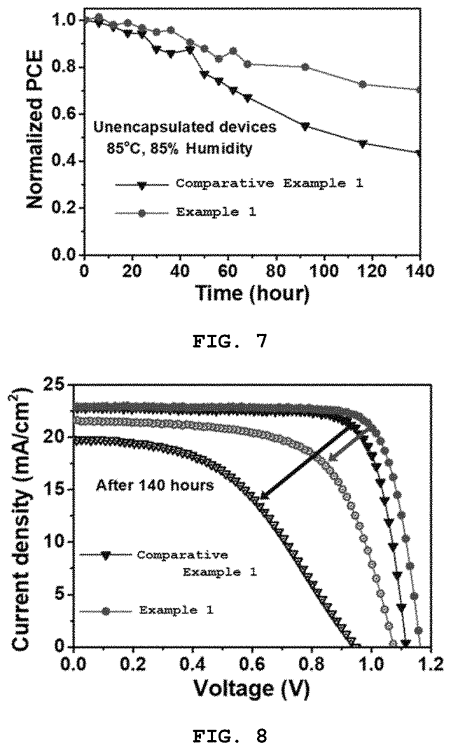

FIG. 7 shows the results of evaluation of stability over time under conditions of 85° C. and a humidity of 85% of the solar cell manufactured in Example 1 and Comparative Example 1, and FIG. 8 shows the current density-voltage curve after 140 hr of the solar cell manufactured in Example 1 and Comparative Example 1.

As shown in FIGS. 7 and 8, the solar cell of Example 1 under conditions of 85° C. and a humidity of 85% maintained 70% of the initial efficiency thereof after 140 hr, but the solar cell of Comparative Example 1 maintained only 43% of the initial efficiency thereof.

Therefore, it can be concluded that the solar cell manufactured in Example 1 exhibits superior stability not only under typical conditions but also under high-temperature and high-humidity conditions.

The scope of the invention is defined by the claims below rather than the aforementioned detailed description, and all changes or modified forms that are capable of being derived from the meaning, range, and equivalent concepts of the appended claims should be construed as being included in the scope of the present invention.

What is claimed is:

1. A modified electron transport layer, comprising:
a metal oxide layer comprising a metal oxide; and
a zwitterion layer formed on the metal oxide layer and comprising a zwitterion.

2. The modified electron transport layer of claim 1, wherein the metal oxide is an n-type metal oxide.

3. The modified electron transport layer of claim 2, wherein the metal oxide comprises at least one selected from the group consisting of SnO₂, ZnO, TiO₂, Al₂O₃, MgO, Fe₂O₃, WO₃, In₂O₃, BaTiO₃, BaSnO₃ and ZrO₃.

4. The modified electron transport layer of claim 1, wherein the zwitterion comprises at least one selected from the group consisting of a compound represented by Structural Formula 1 below and a compound represented by Structural Formula 2 below: 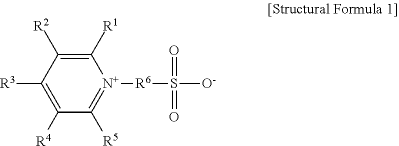
in Structural Formula 1,
R¹ to R⁵ are same as or different from each other, and are each independently a hydrogen atom, a linear C1 to C9 alkyl group, or a branched C3 to C9 alkyl group, and
R⁶ is a linear C1 to C9 alkylene group or a branched C2 to C9 alkylene group; and 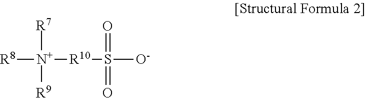
in Structural Formula 2,
R⁷ to R⁹ are same as or different from each other, and are each independently a hydrogen atom, a linear C1 to C9 alkyl group, or a branched C3 to C9 alkyl group, and
R¹⁰ is a linear C1 to C9 alkylene group or a branched C2 to C9 alkylene group.

5. The modified electron transport layer of claim 4, wherein R¹ to R⁵ are same as or different from each other, and are each independently a hydrogen atom or a linear C1 to C9 alkyl group,
R⁶ is a linear C1 to C9 alkylene group,
R⁷ to R⁹ are same as or different from each other, and are each independently a hydrogen atom or a linear C1 to C9 alkyl group, and
R¹⁰ is a linear C1 to C9 alkylene group.

6. The modified electron transport layer of claim 1, wherein the metal oxide layer has a thickness of 10 to 60 nm.

7. The modified electron transport layer of claim 1, wherein the zwitterion layer has a thickness of 0.5 to 10 nm.

8. The modified electron transport layer of claim 1, wherein the electron transport layer is used as an electron transport layer for a solar cell.

9. A solar cell, comprising:
a first electrode;
a metal oxide layer formed on the first electrode and comprising a metal oxide;
a zwitterion layer formed on the metal oxide layer and comprising a zwitterion;
a photoconversion layer formed on the zwitterion layer;
a hole transport layer formed on the photoconversion layer; and
a second electrode formed on the hole transport layer.

10. The solar cell of claim 9, wherein the photoconversion layer comprises at least one selected from the group consisting of a perovskite-structured compound, a dye and a quantum dot.

11. The solar cell of claim 10, wherein the perovskite-structured compound comprises at least one selected from the group consisting of CH₃NH₃PbI₃₋ₓClₓ (0≤x≤3, a real number), CH₃NH₃PbI₃₋ₓBrₓ (0≤x≤3, a real number), CH₃NH₃PbCl₃₋ₓBrₓ (0≤x≤3, a real number), CH₃NH₃PbI₃₋ₓFₓ (0≤x≤3, a real number), NH₂CH═NH₂PbI₃₋ₓClₓ (0≤x≤3, a real number), NH₂CH═NH₂PbI₃₋ₓBrₓ (0≤x≤3, a real number), NH₂CH═NH₂PbCl₃₋ₓBrₓ (0≤x≤3, a real number), NH₂CH═NH₂PbI₃₋ₓFₓ (0≤x≤3, a real number), Csₓ(MA_{0.17}FA_{0.83})₍₁₋ₓ₎Pb(I_{0.83}Br_{0.17})₃ (0≤x≤1, a real number) and Csₖ(NH₂CH═NH₂PbI₃)₍₁₋ₖ₋ₓ)(CH₃NH₃PbBr₃)ₓ (0≤k≤0.3, a real number, and 0≤x≤1−k, a real number).

12. The solar cell of claim 9, wherein the hole transport layer comprises at least one selected from the group consisting of Spiro-OMeTAD, P3HT, P3AT, P3OT, PEDOT:PSS, PTAA and a conductive polymer.

13. The solar cell of claim 9, wherein the first electrode comprises at least one selected from the group consisting of indium tin oxide (ITO), fluorine tin oxide (FTO), indium zinc oxide (IZO), indium zinc tin oxide (IZTO), aluminum zinc oxide (AZO), indium tin oxide-silver-indium tin oxide (ITO—Ag—ITO), indium zinc oxide-silver-indium zinc oxide (IZO—Ag—IZO), indium zinc tin oxide-silver-indium zinc tin oxide (IZTO—Ag—IZTO) and aluminum zinc oxide-silver-aluminum zinc oxide (AZO—Ag—AZO).

14. The solar cell of claim 9, wherein the second electrode comprises at least one selected from the group consisting of Ag, Au, Al, Fe, Cu, Cr, W, Mo, Zn, Ni, Pt, Pd, Co, In, Mn, Si, Ta, Ti, Sn, Pb, V, Ru, Ir, Zr, Rh and Mg.

15. The solar cell of claim 9, wherein the solar cell is any one selected from the group consisting of a dye-sensitized solar cell, a perovskite solar cell and a quantum-dot solar cell.

16. A method of manufacturing a solar cell, comprising:
(a) forming a metal oxide layer comprising a metal oxide on a first electrode;
(b) forming a zwitterion layer comprising a zwitterion on the metal oxide layer;
(c) forming a photoconversion layer on the zwitterion layer;
(d) forming a hole transport layer on the photoconversion layer; and
(e) forming a second electrode on the hole transport layer.

17. The method of claim 16, wherein step (b) is performed through at least one process selected from the group consisting of spin coating and chemical bath deposition.

18. The method of claim 16, wherein the metal oxide layer has a thickness of 10 to 60 nm and the zwitterion layer has a thickness of 0.5 to 10 nm.
